(19) United States
(12) Patent Application Publication
(10) Pub. No.: US 2025/0112181 A1
(43) Pub. Date: Apr. 3, 2025

(54) BONDING STRUCTURES HAVING NON-VERTICAL EDGES FOR SELF-ALIGNMENT ASSISTED ASSEMBLY OF INTEGRATED CIRCUIT DIE STACKS

(71) Applicant: Intel Corporation, Santa Clara, CA (US)

(72) Inventors: Feras Eid, Chandler, OR (US); Yi Shi, Chandler, AZ (US); Kimin Jun, Portland, OR (US); Adel Elsherbini, Chandler, AZ (US); Thomas Sounart, Chandler, AZ (US); Wenhao Li, Chandler, AZ (US); Xavier Brun, Hillsboro, OR (US)

(73) Assignee: Intel Corporation, Santa Clara, CA (US)

(21) Appl. No.: 18/374,522

(22) Filed: Sep. 28, 2023

(51) Int. Cl. H01L 23/00; H01L 23/367; H01L 25/065

(52) U.S. Cl. CPC H01L 24/05; H01L 23/3672; H01L 24/29; H01L 25/0655; H01L 2224/05022; H01L 2224/05701; H01L 2224/29026; H01L 2924/1421; H01L 2924/1427

(57) ABSTRACT

Hybrid bonded die stacks, related apparatuses, systems, and methods of fabrication are disclosed. An integrated circuit (IC) die and a surface of a substrate each include hybrid bonding regions surrounded by hydrophobic structures. The hydrophobic structures include non-vertical inward sloping sidewalls or similar features to contain a liquid droplet that is applied to the die or substrate hybrid bonding region. After the hybrid bonding regions are brought together, capillary forces cause the die to self-align, and a hybrid bond is formed by evaporating the liquid and subsequent anneal. IC structures including the IC die and portions of the substrate are segmented and assembled.

### BACKGROUND

The integrated circuit industry is continually striving to produce ever faster, smaller, and more efficient integrated circuit devices, packages, and systems for use in various electronic products. Current die stacks can be formed using solder to solder bump attachment techniques. For example, on two separate dies, solder bumps may be deposited on copper pillars. The solder bumps may then be brought into contact to join the dies, and underfill material may be formed between the solder bonds and copper pillars. Such processes disadvantageously necessitate a large distance between the bonded dies.

Alternatively, hybrid bonds may be formed between corresponding metallic bond pads on the two dies, with the metallic bond pads interspersed among dielectric material (e.g., an oxide). Prior to bonding, the surface of each die may be controlled to promote bonding by providing a recess of the metallic bond pads relative to the dielectric material, having the dielectric material be planar and relatively smooth, and others. The dies, having mirror image bond pads, are then brought together such that corresponding metallic bond pads and corresponding dielectric material surfaces of the two dies interface with one another. At room temperature, the dielectric materials adhere sufficiently to one another (due to Van der Waals forces) to maintain a bond. A high temperature anneal is then performed to bond the corresponding metallic bond pads, and to improve the dielectric material bond. Such processes reduce the distance between the bonded dies, reduce pitches between the metal bonds, and offer other advantages. For example, solder bump techniques may be limited to pitches of about 30 μm while hybrid bonding can attain less than 10 μm and even less than 1 μm pitches.

However, difficulties in forming 3D die stacks using hybrid bonding techniques persist. It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 provides a flow diagram illustrating an example process for fabricating IC structures inclusive of 3D die stacks with hybrid bonding regions surrounded by hydrophobic features having non-vertical edges;

FIGS. 2, 3, 4, 5, 6, 7, 8, 9, 10, 11, 12, and 13 are illustrations of cross-sectional side views of integrated circuit (IC) structures having hydrophobic features with non-vertical edges being prepared for self-alignment bonding;

FIGS. 14, 15, 16, and 17 are illustrations of cross-sectional side views of IC structures during self-alignment hybrid bonding and subsequent dielectric fill and support structure bonding;

FIG. 18 is an illustration of a cross-sectional side view of an assembly structure similar to the IC structure of FIG. 17 after packaging and deployment of heat removal solutions;

FIG. 19 illustrates exemplary systems deploying a 3D die stack having a hybrid bond with dielectric material between an outer perimeter edge of a bonding structure and a substrate or an IC die; and

FIG. 20 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Integrated circuit structures, 3D die stack structures, devices, apparatuses, systems, and methods are described herein related to hydrophilic hybrid bonding structures having hydrophobic non-vertical edges to contain alignment liquid during hybrid bonding.

As described above, hybrid bonding techniques offer advantages in the assembly of 3D die stacks. As used herein, the term 3D die stack indicates a stack of devices or structures having at least partially vertically aligned layers such that layers of the 3D die stack may employ one or more IC dies each. The term layer or level of a 3D die stack indicates a horizontal portion of the 3D die stack that includes only one depth of device within the horizontal portion (e.g., each layer may have any number of IC dies in the horizontal plane). The term IC die includes any monolithic integrated device that provides electrical, compute, memory, or similar functionality. IC dies include chiplets, chiplet dies, memory dies, processor dies, routing dies, and so on. Herein, the terms chiplet and IC die are used interchangeably. An IC die may be passive such that it only includes electrical routing, or it may be active such that it includes electrical devices such as transistors, capacitors, etc. The term base substrate, base wafer, or base die indicates a substrate having active or passive electrical features. In contrast, the term structural substrate, structural wafer, or structural die indicates a substrate absent any active or passive electrical features. For example, a structural substrate may be a monolithic material such as silicon, or other base material that provides structural support and heat removal. In some embodiments, an IC die may be an integral part of a wafer during hybrid bonding processing, and the IC die and other components may be diced from the wafer after bonding or other hybrid bonding processing, and assembled into an electronic device.

In the context of hybrid bonding of IC dies, faster throughput may be attained during die-to-wafer hybrid bonding (D2W HB) using self-alignment assisted assembly (SA3). In SA3 process flows, a liquid droplet is dispensed on the bonding area on either the top chiplet die or the base wafer to be bonded. A bonder is then used to pick and place the chiplet die onto the base wafer at coarse alignment (e.g., ˜ 25-50 μm), such that the water droplet is sandwiched in the bonding area between the chiplet and the base wafer. Capillary forces cause the chiplet to self-align to its desired bonding location on the wafer with high positional accuracy (e.g., <200 nm) due to containment features (e.g., SA3 features) designed into the chiplet die and base wafer that confine the droplet to the bonding area with high precision. Such containment features may be characterized as alignment features, SA3 features, or the like. The liquid then evaporates, leaving the chiplet bonded to the base wafer at room temperature due to attractive surface forces (e.g., Van der Waals forces) between the dielectric regions on the chiplet and base wafer. An annealing step is then carried out to form and/or strengthen bonds between the metal pads (e.g., copper pads) dispersed between the dielectric regions, forming electrical interconnects between the chiplet and base wafer. The annealing step may also strengthen the bond between the dielectric regions.

However, one of the challenges with this approach is that the liquid must be contained within the hybrid bonding region prior to and during bonding. The techniques discussed herein address these challenges by implementing non-vertical edges and other edge features around the hybrid bonding region such that the edge of the sidewall has a gap between the edge and the underlying substrate. The non-vertical edge may have a low angle inward sloping sidewall (e.g., having an angle between a top surface of the hybrid bonding region and the sidewall that is <90°) or it may have a thin overhanging or cantilevered structure that effectively provides a 0° edge angle for the hybrid bonding region. In some embodiments, the sidewall or overhanging structure is also coated in a hydrophobic material to aid in containing the alignment liquid (e.g., water). The discussed structures enable better physical contrast between the hybrid bonding region and the surrounding region that enhances liquid confinement. In some contexts, the improved physical contrast can eliminate the need for the chemical contrast provided by a hydrophobic material coating. Eliminating use of the hydrophobic material coating offers the advantages of simplified fabrication processing, reduced contamination, and others. In other contexts the use of the hydrophobic material coating further enhances the liquid containment. Such structures offer high performance liquid containment during hybrid bonding. Other advantages will be evident from the following discussion.

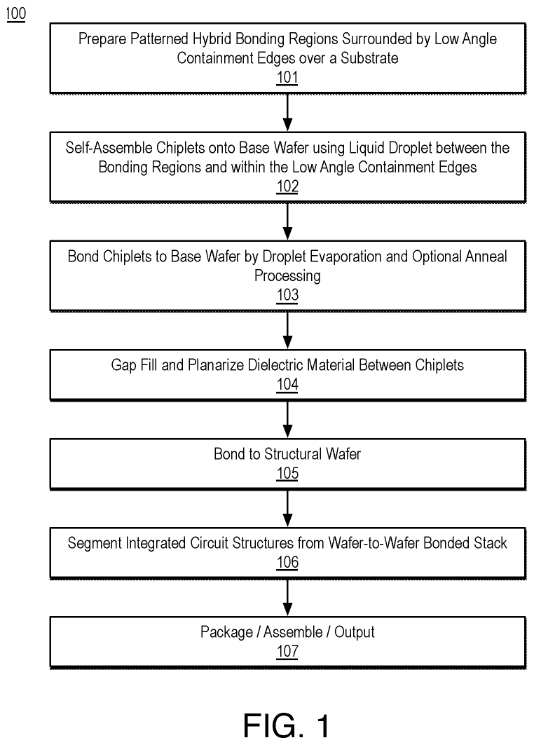

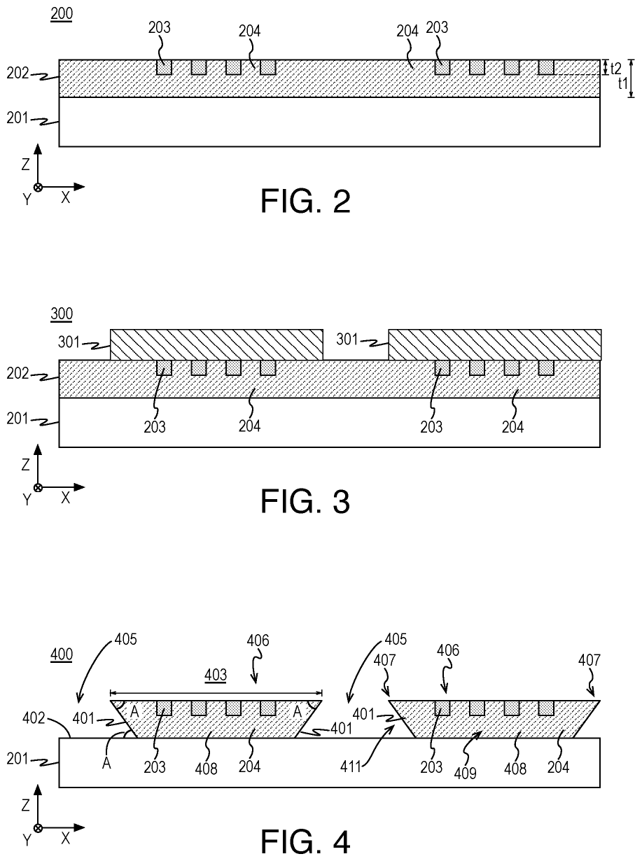

FIG. 1 provides a flow diagram illustrating an example process 100 for fabricating IC structures inclusive of 3D die stacks with hybrid bonding regions surrounded by hydrophobic features having non-vertical edges, arranged in accordance with at least some implementations of the present disclosure. For example, process 100 may be implemented to fabricate IC structure 1700, assembly structure 1800, or any other structure discussed herein. In the illustrated embodiment, process 100 includes one or more operations as illustrated by operations 101-107. However, embodiments herein may include additional operations, certain operations being omitted, or operations being performed out of the order provided. FIGS. 2-18 illustrate structures and components as the methods of process 100 are practiced.

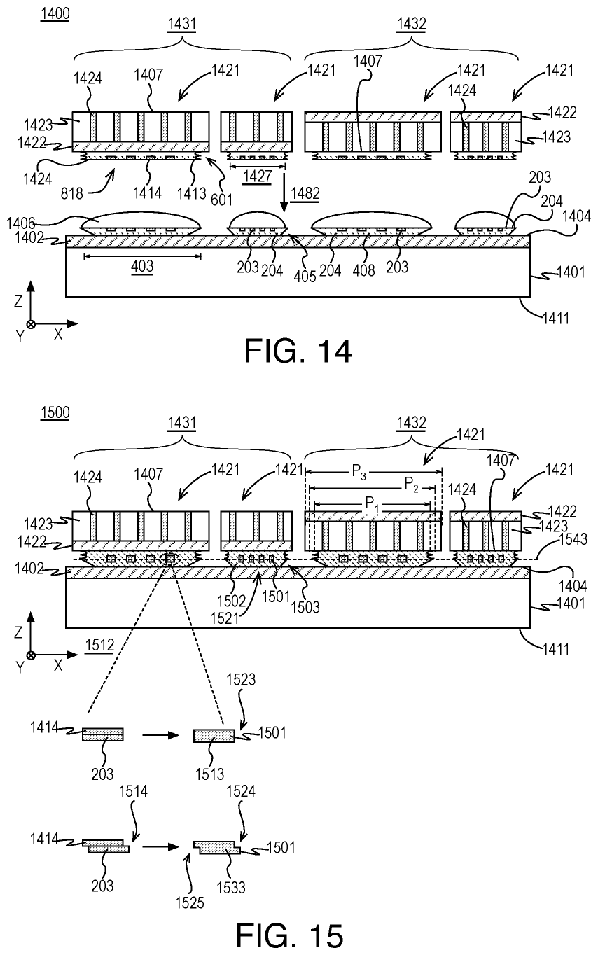

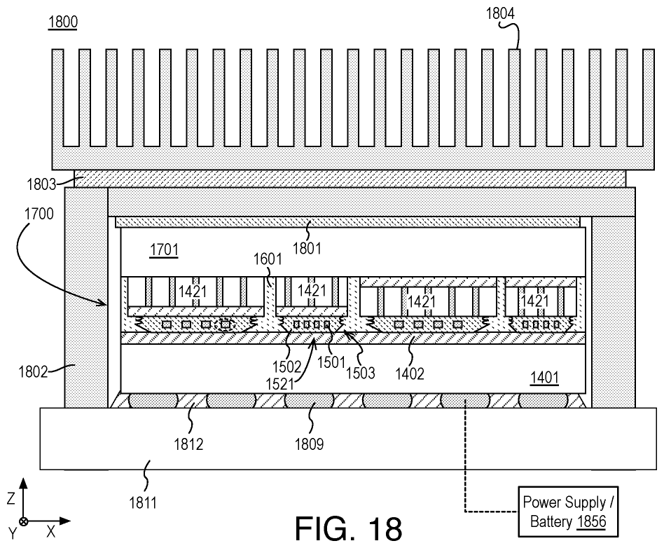

FIGS. 2, 3, 4, 5, 6, 7, 8, 9, 10, 11, 12, and 13 are illustrations of cross-sectional side views of integrated circuit (IC) structures having hydrophobic features with non-vertical edges being prepared for self-alignment bonding, arranged in accordance with at least some implementations of the present disclosure. FIGS. 14, 15, 16, and 17 are illustrations of cross-sectional side views of IC structures during self-alignment hybrid bonding and subsequent dielectric fill and support structure bonding, arranged in accordance with at least some implementations of the present disclosure. FIG. 18 is an illustration of a cross-sectional side view of an assembly structure similar to the IC structure of FIG. 17 after packaging and deployment of heat removal solutions, arranged in accordance with at least some implementations of the present disclosure.

Process 100 begins at operation 101, where hybrid bonding regions surrounded by hydrophobic containment features are prepared over a base wafer and on IC dies or chiplets. In process 100, IC dies or chiplets are attached to a base wafer or substrate such that they may be directly attached to the base wafer or substrate or to a layer or level of IC dies or chiplets previously assembled. Such attachment techniques place the IC dies or chiplets onto the base substrate quickly and with gross alignment and then use a liquid droplet between a bonding region of the placed IC die or chiplet and a corresponding bonding region of the base substrate to provide fine alignment using capillary forces. Such self-alignment bonding techniques allow for high throughput as high accuracy, long duration pick and place alignment is not needed.

Notably, the ability of the liquid droplet to spread within the hybrid bonding region and be fully contained therein by the surrounding hydrophobic containment features is an important aspect of the self-alignment bonding. The techniques and structures discussed herein provide structures or architectures where the hybrid bonding structure is surrounded by a trench with the hybrid bonding structure having an inward taper (e.g., the angle formed between bonding plane and the trench sidewall is less than 90°) or similar characteristics. This structure or architecture increases the liquid confinement capability of the trench. In some embodiments, an outer upper edge of the hybrid bonding structure extends outwardly from an interior bulk portion of the hybrid bonding structure such that a gap is between the outer upper edge of the hybrid bonding structure and the underlying substrate. This gap may later be filled with a dielectric material. The discussed structures or architectures improve liquid droplet confinement and allow for reduction of the depth of the trench. For example, prior trenches must be very deep (e.g., 10-15 microns) to provide adequate liquid containment while the trenches discussed herein may be much less (e.g., about 0.5-5 microns), which may further reduce the gap between the devices being hybrid bonded.

FIG. 2 is an illustration of a cross-sectional side view of an IC structure 200 that will be prepared for self-alignment bonding. As shown, IC structure 200 includes a substrate 201 and a hybrid bonding layer 202 formed on substrate 201. Substrate 201 may be a base wafer (as discussed further herein below) or a structural wafer or panel or the like on which IC dies or chiplets are being prepared for hybrid bonding. For example, substrate 201 may be a monolithic material, a crystalline material, or a composite material structural material or substrate 201 may be a base substrate including an interconnect layer, optional device layer, and routing through substrate 201 for connection to an outside package or board.

Hybrid bonding layer 202 includes metal bond pads 203 interspersed in an inorganic dielectric material 204. Inorganic dielectric material 204 may be any suitable material for forming a bond between hybrid bonding layer 202 and another hybrid bonding layer. As used herein, the term inorganic material indicates materials not having carbon as a foundational component or materials not having carbon-hydrogen bonds. In some embodiments, inorganic dielectric material 204 is silicon oxide. In some embodiments, inorganic dielectric material 204 is silicon nitride, silicon oxynitride, silicon carbonitride, or silicon carbide. In some embodiments, the out facing surface of hybrid bonding layer 202 may be planarized to a smooth finish for subsequent bonding. Metal bond pads 203 may be any suitable material for forming a bond between hybrid bonding layer 202 and another hybrid bonding layer and a suitable conductor for the application at hand. In some embodiments, metal bond pads 203 are copper but other metals may be used. In some embodiments, a bulk inorganic dielectric material is formed over substrate 201 and planarized. Metal bond pads 203 are then formed using any suitable technique or techniques such as single or dual damascene techniques.

As shown, in some embodiments, hybrid bonding layer 202 has a thickness t1 (i.e., from a top surface of substrate 201 to a top surface of hybrid bonding layer 202) while metal bond pads 203 have a thickness of t2. In some embodiments, thickness t1 is in the range of 0.5 to 5 microns such as a thickness of about 2 to 3 microns. In some embodiments, thickness t2 is in the range of 0.5 to 2 microns such as a thickness of about 1 to 1. 5 microns. However, other thicknesses may be used. In other embodiments, metal bond pads 203 and hybrid bonding layer 202 have the same thickness.

FIG. 3 illustrates an IC structure 300 similar to IC structure 200 after formation of a patterned layer 301 to define hybrid bonding regions for eventual self-aligned bonding. Patterned layer 301 may be formed using any suitable technique or techniques such as lithography techniques including bulk layer deposition of a photosensitive material, exposure, and developing where the exposed material or the unexposed material is removed. Patterned layer 301 may include any suitable patterning material such as resist, hardmask materials, and so on. Patterned layer 301 defines hybrid bonding regions where eventual self-alignment assisted features will be used for hybrid bonding alignment. The regions under patterned layer 301 will be the hybrid bonding region and will allow an alignment assisting liquid droplet to spread out thereon. The hybrid bonding region may be characterized as a hydrophilic structure, surface, or region. Surrounding the hybrid bonding region, hydrophobic structures, architectures, and materials will contain the alignment assisting liquid droplet on the hydrophilic structure, surface, or region.

FIG. 4 illustrates an IC structure 400 similar to IC structure 300 after formation of hydrophilic structures 408 surrounded by hydrophobic trenches 405 for self-aligned bonding, and removal of patterned layer 301. As discussed, hydrophilic structures 408 include metal bond pads 203 interspersed in inorganic dielectric material 204, which may be silicon oxide, silicon nitride, silicon oxynitride, silicon carbonitride, or silicon carbide. Such materials are hydrophilic such that a liquid (e.g., water) will spread out on hydrophilic structures 408 as the liquid minimizes its surface energy. Patterned hydrophilic structures 408 therefore define hybrid bonding regions 403, which will be bonded to corresponding hybrid bonding regions to build 3D die stacks, as discussed further herein below.

Hydrophilic structures 408 and hydrophobic trenches 405 provide an inward sidewall 401 of hydrophilic structures 408 that extends from an outer upper edge 407 of hydrophilic structures 408 toward a center region or position 409 of hydrophilic structures 408. The term outer upper edge is used in its ordinary meaning to indicate a furthest lateral position or perimeter of hydrophilic structures 408. Similarly, the term center region or position is used to indicate the lateral center of hydrophilic structures 408, which may be centroid of hybrid bonding regions 403 in the x-y plane, for example.

As shown, inward sidewall 401 and bonding plane 406 (e.g., the top surface of hydrophilic structure 408) provide an angle A, therebetween. In some embodiments, bonding plane 406 is substantially parallel to top surface 402 as both are in the x-y plane. Angle A may be any angle less than 90°. In some embodiments, angle A is in the range of 1° to 89°. In some embodiments, angle A is not more than 75°. In some embodiments, angle A is not more than 60°. In some embodiments, angle A is not more than 45°. In some embodiments, angle A is not more than 30°. In some embodiments, angle A is not more than 15°. The angle A may depend on process parameters used to create hydrophobic trenches 405, the material of inorganic dielectric material 204, and others.

In some embodiments, inward sidewall 401 is a substantially planar surface that extends inwardly from adjacent bonding plane 406 to a top surface 402 of substrate 201 (such that an angle between top surface 402 and inward sidewall 401 is also angle A). For example, inward sidewall 401 may have a constant inward taper. In some embodiments, inward sidewall 401 has a sidewall portion that extends inwardly from adjacent bonding plane 406 toward top surface 402 but inward sidewall 401 also includes other features such as scallops, etch ridges, discontinuities, or others between outer upper edge 407 and top surface 402 of substrate 201. As used herein, the term adjacent relative to bonding plane 406 is used to indicate the sidewall portion of inward sidewall 401 is within zero to about 100 nm of outer upper edge 407. For example, outer upper edge 407 may not extend to a sharp edge as illustrated but may be rounded, have a slight curvature, or the like. The pertinent inward sidewall 401 may extend any distance from this position such as 100 nm to the entirety of the distance to top surface 402.

Inward sidewall 401 further provides a gap 411 between outer upper edge 407 and top surface 402 of substrate 201. Gap 411 has at least a portion thereof that extends vertically between outer upper edge 407 and top surface 402 of substrate 201. Gap 411 has a portion that extends vertically between inward sidewall 401, or at least a portion of inward sidewall 401, and top surface 402 of substrate 201. As discussed herein below, gap 411 will be filled with a dielectric material such a second inorganic dielectric material or an organic dielectric material such that the dielectric material is between outer upper edge 407 and top surface 402 of substrate 201 and between inward sidewall 401, or at least a portion of inward sidewall 401, and top surface 402 of substrate 201.

Hydrophilic structures 408 and hydrophobic openings or hydrophobic trenches 405 may be formed from hybrid bonding layer 202 using any suitable technique or techniques such as wet or dry etch techniques. In some embodiments, multiple etch cycles are deployed to form inward sidewall 401. In some embodiments, inorganic dielectric material 204 is or includes crystalline or polycrystalline portions that may be susceptible to angled etch processing. In some embodiments, inorganic dielectric material 204 is or includes an amorphous material and single or multiple etch cycles may be deployed to fabricate inward sidewall 401. For example, inward sidewall 401 may be fabricated by proper optimization of the wet or dry etch processes used to create the hydrophobic structures defined by hydrophobic trenches 405. Patterned layer 301 may be removed using any suitable technique or techniques such as ashing techniques.

in Notably, using the structures and techniques discussed herein, new structures and architectures are fabricated to improve liquid confinement within hybrid bonding regions 403 while also enabling shallow trenches defined by hydrophobic trenches 405. While not being restricted by theory, the improved liquid confinement may be based on the canthotaxis effect, in which the liquid confinement ability of a trench defined by hydrophobic structures such as hydrophobic trenches 405 is proportional to (180°-A). By making angle A as small as possible, this effect is maximized.

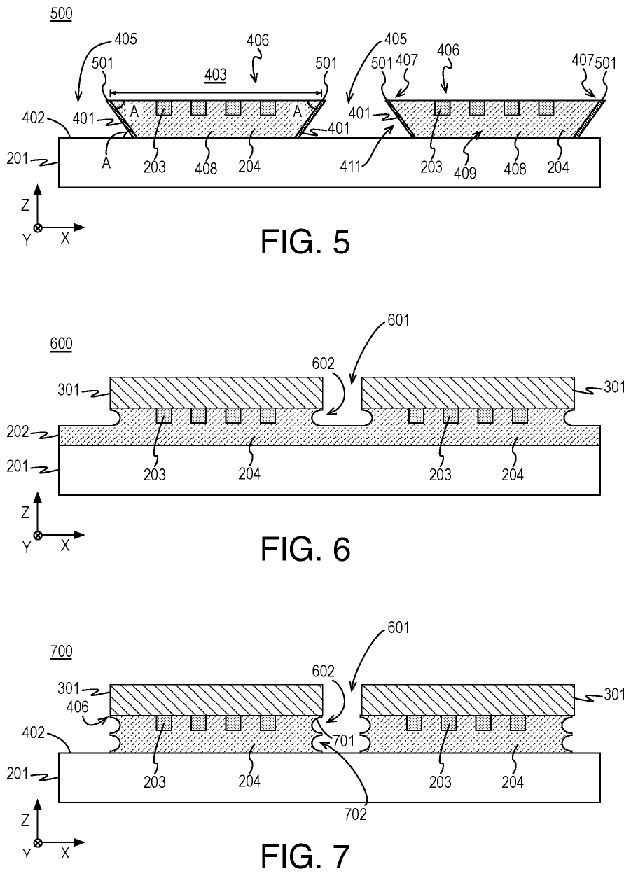

FIG. 5 illustrates an IC structure 500 similar to IC structure 400 after formation of hydrophobic structures 501 adjacent hydrophilic structures 408. Hydrophobic structures 501 may be formed on inward sidewall 401 of hydrophilic structures 408 using any suitable technique or techniques. In some embodiments, a conformal hydrophobic material layer is formed on exposed surfaces of hydrophilic structures 408 and substrate 201 using, for example, spin coating or conformal vapor deposition. The conformal hydrophobic material layer is then removed from the lateral or horizontal surfaces while the conformal hydrophobic material layer remains on inward sidewall 401 via an anisotropic etch such as a dry etch.

Hydrophobic structures 501, which may be characterized as hydrophobic spacers, hydrophobic materials, or the like may include any suitable hydrophobic material (e.g., material that causes a liquid water droplet to have a contact angle of greater than 90°). In some embodiments, hydrophobic structures 501 are chemical coatings or hydrophobic materials that create a hydrophobic boundary with a large contact angle (e.g., >90°) around hybrid bonding regions 403. In some embodiments, the hydrophobic material of hydrophobic structures 501 is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may be used. In some embodiments, the hydrophobic material of hydrophobic structures 501 is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used. In accordance with some embodiments of the present disclosure, structures 412 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

Hydrophobic structures 501 will further contain a liquid within hybrid bonding regions 403 while hydrophilic structures 408 allow the liquid to spread out in hybrid bonding regions 403. In the embodiment of FIG. 5, hybrid bonding regions 403 are within hydrophobic trenches 405 and hydrophobic structures 501 having hydrophobic materials. Notably, both hydrophobic trenches 405 and hydrophobic structures 501 may be characterized as hydrophobic structures that use architecture and materials, respectively, as their mechanism of hydrophobicity. The embodiment of FIG. 4, absent hydrophobic structures 501 offers the advantages of simplicity of manufacture and may limit contamination in further processing. The embodiment of FIG. 5 offers the advantages of multiple and diverse hydrophobic structures (e.g., both material and structure based hydrophobic structures) at the cost of increased fabrication complexity.

Discussion now turns to an alternative for fabricating hydrophobic trenches that deploys multiple cycles such that, after an initial isotropic etch process, each cycle includes depositing a passivation material followed by an isotropic etch operation to fabricate a trench, as is known in the art. Such processing may be cycled through any number of times to form trenches without the need to remove the workpiece from the processing chamber. For example, both the passivation material deposition and etch processing may be performed in the same processing chamber by changing the chemistry within the chamber.

FIG. 6 illustrates an IC structure 600 similar to IC structure 300 after a first etch cycle forms a first scallop 602 in inorganic dielectric material 204. As shown in FIG. 6, first scallop 602 is formed by an isotropic etch of a portion of inorganic dielectric material 204 to begin a hydrophobic trench 601. Scallop 602 may also be characterized as an isotropic gap, an etch gap, a rounded out profile, an undercut, or the like. Scallop 602 and the corresponding opening may be formed using any suitable isotropic etch chemistry.

FIG. 7 illustrates an IC structure 700 similar to IC structure 600 after passivation material deposition (not shown) and a second etch cycle forms a second scallop 702 in inorganic dielectric material 204 to continue or complete hydrophobic trench 601. Second scallop 702 may have the same characteristics as first scallop 602 or they may be different. Notably, first scallop 602 defines an inward sidewall portion 701 that has a non-vertical edge relative to bonding plane 406, as discussed further below. Second scallop 702 and any other additional scallops continue to form hydrophobic trench 601, which may be a high aspect ratio trench in some embodiments.

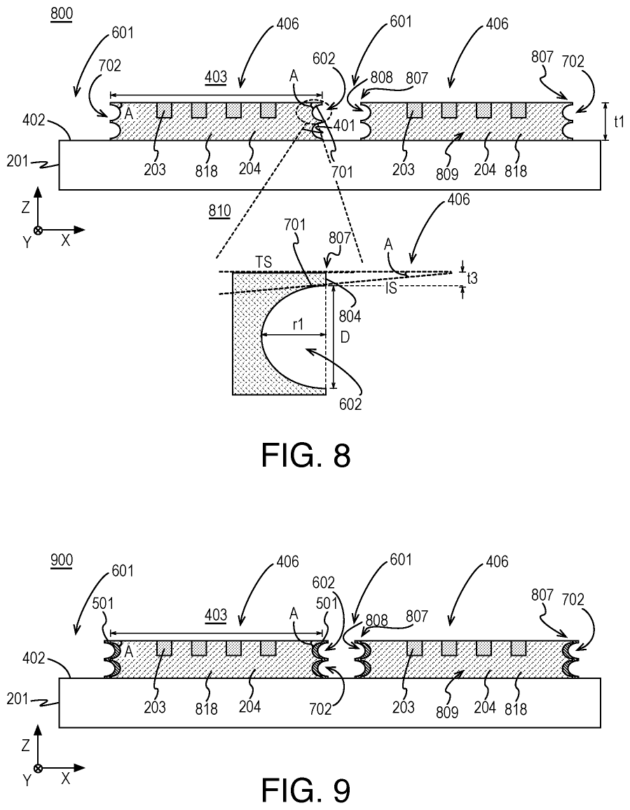

FIG. 8 illustrates an IC structure 800 similar to IC structure 700 after removal of patterned layer 301. Patterned layer 301 may be removed using any suitable technique or techniques such as ashing techniques. Although illustrated with respect to two etch cycles such that IC structure 800 is fabricated by a process of: an isotropic etch, a passivation material deposition, and an isotropic etch, any number of cycles may be used and any number corresponding scallops may be formed in inorganic dielectric material 204.

Such processing fabricates hydrophilic structures 818 surrounded by hydrophobic trenches 601 for self-aligned bonding. Hydrophilic structures 818 include metal bond pads 203 interspersed in inorganic dielectric material 204, which may be silicon oxide, silicon nitride, silicon oxynitride, silicon carbonitride, or silicon carbide. As discussed, such materials are hydrophilic such that a liquid (e.g., water) will spread out on hydrophilic structures 818 and across hybrid bonding regions 403.

Hydrophilic structures 818 and the scalloped patterning of hydrophobic trenches 601 provide an inward sidewall portion 701 of each hydrophilic structure 818 that extends from adjacent an outer upper edge 807 of hydrophilic structures 818 toward a center region or position 809 of hydrophilic structures 818. As shown in enlarged view 810, inward sidewall portion 701 and bonding plane 406 (e.g., the top surface of hydrophilic structure 408) provide an angle A, therebetween. Angle A may be any angle less than 90°. In some embodiments, angle A is in the range of 1° to 89°. In some embodiments, angle A is not more than 75°, not more than 60°, not more than 45°, not more than 30°, not more than 15°, or not more than 5°. The angle A may depend on process parameters used to create first scallop 602, the material of inorganic dielectric material 204, and others. In some embodiments, angle A is defined between bonding plane 406 and a tangent of a portion of a sidewall of scallop 602 such that the tangent is taken at or within 100 nm of the point of the opening of scallop 602 opposite a vertical sidewall portion 804 from outer upper edge 807. In other embodiments, the opening begins at outer upper edge 807 and no vertical sidewall portion 804 is present. In such contexts, angle A is defined between bonding plane 406 and a tangent of a portion of a sidewall of scallop 602 such that the tangent is taken at or within 100 nm of outer upper edge 807.

In some embodiments, inward sidewall portion 701 is a curved surface that extends inwardly from adjacent bonding plane 406 such that a substantially vertical sidewall portion 804 is between inward sidewall portion 701 and outer upper edge 807. Vertical sidewall portion 804 may have a relatively small thickness t3 in the vertical direction such that a liquid droplet substantially interacts with inward sidewall portion 701 to define the hydrophobicity at outer upper edge 807. Thickness t3 may be any suitable thickness such as a thickness in the range of one to 300 nm. In some embodiments, thickness t3 is not more than 100 nm. In some embodiments, thickness t3 is not more than 20 nm. As shown in enlarged view 810, bonding plane 406 may be a top surface TS of hydrophilic structure 818 such that top surface TS is a plane substantially in the x-y plane. Inward sidewall portion 701 defines an inward sidewall plane IS that is tangential to inward sidewall portion 701 at or near an edge of vertical sidewall portion 804 opposite outer upper edge 807. In some embodiments, inward sidewall plane IS may be defined within scallop 602 such as a position 1 to 200 nm within a radius r1 of scallop 602. For example, scallop 602 (e.g., hydrophobic trench 601 having scalloping) produces an effective inward taper from hybrid bonding regions 403. As discussed above, in some embodiments, vertical sidewall portion 804 is not present.

Scallop 602 may have any suitable diameter D (and corresponding inlet radius r1=D/2). In some embodiments, scallop 602 has a diameter D in the range of 20 nm to 1 micron. As discussed above, hydrophilic structures 818 may have a thickness t1 in the range of 0.5 to 5 microns such as a thickness of about 2 to 3 microns. For example, hydrophobic trenches 601 may have two to hundreds of scallops. As discussed, an uppermost scallop 602 defines inward sidewall portion 701, which forms an angle A with respect to bonding plane 406. Inward sidewall portion 701 is a region of scallop 602, with scallop 602 extending from outer upper edge 807 of hydrophilic structure 818 toward top surface 402 of substrate 201.

Inward sidewall portion 701 and scallops 602, 702 further provides or defines a gap 808 between outer upper edge 807 and top surface 402 of substrate 201. Gap 808 has at least a portion thereof that extends vertically between outer upper edge 807 and top surface 402 of substrate 201. Gap 808 further has a portion that extends vertically between inward sidewall portion 701, or at least a portion of inward sidewall portion 701, and top surface 402 of substrate 201. Eventually, gap 808 will be filled with a dielectric material such a second inorganic dielectric material or an organic dielectric material such that the dielectric material is between outer upper edge 807 and top surface 402 of substrate 201 and between inward sidewall portion 701, or at least a portion of inward sidewall portion 701, and top surface 402 of substrate 201.

FIG. 9 illustrates an IC structure 900 similar to IC structure 800 after formation of hydrophobic structures 501 adjacent hydrophilic structures 818. Hydrophobic structures 501 may be formed using any suitable technique or techniques such as forming a conformal hydrophobic material layer on exposed surfaces of hydrophilic structures 818 followed by removal of the conformal hydrophobic material layer from the lateral or horizontal surfaces while the conformal hydrophobic material layer remains on scallops 602, 702 (including inward sidewall portion 701). As shown, hydrophobic structures 501 are on scallops 602, 702 and vertical sidewall portion 804 (e.g., sidewalls of hydrophobic trenches 601) while being absent on hybrid bonding regions 403.

Hydrophobic structures 501 may include any suitable hydrophobic materials and may have any characteristics discussed above with respect to FIG. 5. For example, hydrophobic structures 501 may be or include a self-assembled monolayer material or a thin polymer film. Hydrophobic structures 501 further contain a liquid within hybrid bonding regions 403 during bonding, as discussed herein. Such material based hydrophobic structures 501 may be deployed in some embodiments for further hydrophobicity.

Discussion now turns to an alternative for fabricating hydrophobic edge structures that provide a thin metal structure extending and cantilevered from the outer edge of the inorganic dielectric material. In some embodiments, a top layer of the embedded metal pads are formed along with the thin metal structure. An etch is then performed to remove the inorganic dielectric material from under the cantilevered thin metal structure leaving an essentially 0° angle at the thin edge.

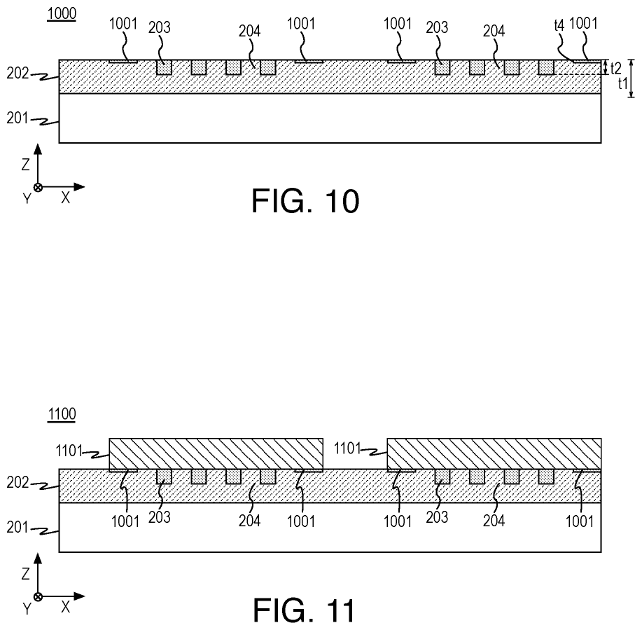

FIG. 10 illustrates an IC structure 1000 similar to IC structure 200 after formation of thin metal structures 1001. In some embodiments, each of metal structures 1001 surrounds a corresponding group of metal bond pads 203. For example, each of metal structures 1001 may eventually extend around a perimeter of and define a corresponding hydrophilic bonding region. As shown, metal structures 1001 may have a thickness t4 that is substantially less than a thickness t2 of each of metal bond pads 203. In some embodiments, thickness t2 is in the range of 0.5 to 2 microns such as a thickness of about 1 to 1.5 microns. Thickness t4 may be in the range of about 2 to 200 nanometers. In some embodiments, thickness t4 is in the range of 5 to 100 nm. In some embodiments, thickness t4 is not more than 50 nm. In some embodiments, thickness t4 is not more than 20 nm. In some embodiments, a ratio thickness t2 to thickness t4 is in the range of 2.5 to 1,000. In some embodiments, a ratio thickness t2 to thickness t4 is not less than 50, not less than 100, or not less than 200.

Metal structures 1001 may be formed using any suitable technique or techniques. In some embodiments, metal structures 1001 are formed in inorganic dielectric material 204 using single or dual damascene techniques. In some embodiments, metal bond pads 203 are initially formed in inorganic dielectric material 204 at a thickness that is the desired end thickness of metal bond pads 203 (t2) less the desired thickness of metal structures 1001 (t4). For example, metal bond pads 203 may be initially formed at a thickness of t4-t2. Then, during formation of metal structures 1001, a top portion of metal bond pads 203 are also fabricated to form metal structures at thickness t4 and to bring metal bond pads to the desired thickness t2. Other techniques may be used. In some embodiments, both metal structures 1001 and metal pads 203 are or include copper. However, other metals may be used.

FIG. 11 illustrates an IC structure 1100 similar to IC structure 1000 after the formation of a patterned layer 1101 to define hybrid bonding regions. Patterned layer 1101 may be formed using any suitable technique or techniques such as lithography techniques. For example, a photosensitive material may be deposited, exposed, and developed to remove exposed material or unexposed material. Patterned layer 1101 may include any suitable patterning material such as resist, hardmask materials, and so on. Patterned layer 1101 defines hybrid bonding regions where self-alignment assisted features will be used for hybrid bonding alignment.

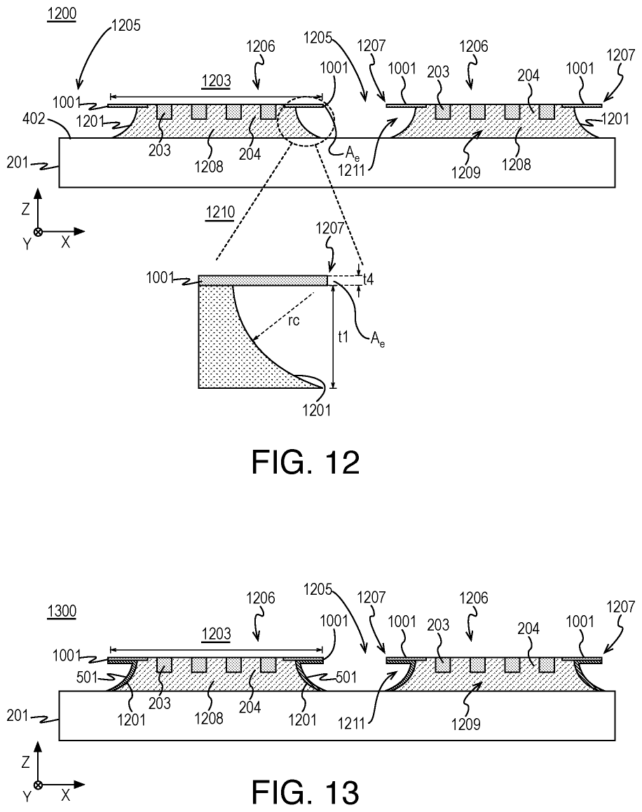

FIG. 12 illustrates an IC structure 1200 similar to IC structure 1100 after formation of hydrophilic structures 1208 surrounded by hydrophobic trenches 1205 for self-aligned bonding, and removal of patterned layer 1101. As discussed, hydrophilic structures 1208 include metal bond pads 203 interspersed in inorganic dielectric material 204, which may be silicon oxide, silicon nitride, silicon oxynitride, silicon carbonitride, or silicon carbide. Hydrophilic structures 1208 define hybrid bonding regions 1203 as discussed herein above. Furthermore, hydrophilic structures 1208 each include a thin metal structure 1001 extending around a perimeter of hybrid bonding regions 1203. Hybrid bonding regions 1203 of hydrophilic structures 1208 provide a hydrophilic surface that a liquid (e.g., water) will spread out on hydrophilic structures 1208 for alignment during bonding.

Hydrophilic structures 1208 and hydrophobic openings or hydrophobic trenches 1205 may be formed from hybrid bonding layer 202 using any suitable technique or techniques such as isotropic wet etch techniques that etch at substantially the same rate in all directions. After etch, patterned layer 1101 may be removed using any suitable technique or techniques such as ashing techniques. The discussed etch defines a sidewall 1201 in hydrophilic structures 1208.

As shown, metal structures 1001 have an outer edge 1207 that defines an outer edge of hydrophilic structures 1208 along a bonding plane 1206, such that bonding plane 1206 is in the x-y plane. Metal structures 1001, after etch, are cantilevered from inorganic dielectric material 204 and provide a thin outer edge 1207 of thickness t4. Thickness t4 may be any thickness discussed above such as a thickness t4 in the range of about 2 to 200 nanometers, a thickness t4 in the range of 5 to 100 nm, a thickness t4 of not more than 50 nm, or a thickness t4 of not more than 20 nm. Such thicknesses provide an effective angle Ae at outer edge 1207 of 0°. This provides very high hydrophobicity at outer edge 1207 due the discussed canthotaxis effect.

The discussed etch provides an inner sidewall 1201 of hydrophilic structures 1208 that extends inwardly from top surface 402 of substrate 201 toward a center region or position 1209 of hydrophilic structures 1208. The removal of portions of inorganic dielectric material 204 further provides a gap 1211 between outer edge 1207 and top surface 402 of substrate 201. As shown, gap 1211 has at least a portion thereof that extends vertically between outer edge 1207 and top surface 402 of substrate 201. Gap 1211 further has a portion that extends vertically between sidewall 1201, or at least a portion of sidewall 1201, and a bottom surface of metal structures 1001. Gap 1211 will be filled with a dielectric material such a second inorganic dielectric material or an organic dielectric material such that the dielectric material is at any position discussed with respect to gap 1211. As further shown in enlarged view 1210, in some embodiments, sidewall 1201 is a curved surface having a radius of curvature rc. The radius of curvature rc may be any suitable value such as a radius of curvature rc in the range 0.1 to 5 microns.

FIG. 13 illustrates an IC structure 1300 similar to IC structure 500 after formation of hydrophobic structures 501 adjacent hydrophilic structures 1208. Hydrophobic structures 501 may be formed on sidewall 1201 and exposed bottom sides of metal structures 1001 using any suitable technique or techniques. In some embodiments, a conformal hydrophobic material layer is formed on exposed surfaces of hydrophilic structures 1208 and substrate 201 using, for example, spin coating or conformal vapor deposition. Subsequently, the conformal hydrophobic material layer is then removed from the lateral or horizontal surfaces via an anisotropic etch such as a dry etch, such that the conformal hydrophobic material layer remains on sidewall 1201 and exposed bottom sides of metal structures 1001.

Hydrophobic structures 501 may include any suitable hydrophobic materials and may have any characteristics discussed above with respect to FIG. 5. For example, hydrophobic structures 501 may be or includes a self-assembled monolayer material or a thin polymer film. Hydrophobic structures 501 further contain a liquid within hybrid bonding regions 403 during bonding, as discussed herein. Such material based hydrophobic structures 501 may be deployed in some embodiments for further hydrophobicity.

Returning to FIG. 1, process 100 continues at operation 102, where dies or chiplets are self-assembled onto a base wafer using a liquid droplet between hybrid bonding regions and within the hydrophobic containment features prepared at operation 101. In some embodiments, the water droplet is applied to a hydrophilic hybrid bonding region over a base substrate. In some embodiments, the water droplet is applied to a hydrophilic bonding region of the IC dies or chiplets. In either event, the IC die hydrophilic bonding region is placed on or over the hydrophilic bonding region of the base substrate (using gross alignment) and the interplay of the droplet, the hydrophilic bonding regions, and the hydrophobic containment features cause the IC die to self-align with high accuracy. Both the IC dies or chiplets and the base wafer hybrid bonding regions may use any of the hydrophobic containment features discussed herein. They may use the same features or they may use different features. In some embodiments, only one of the IC dies or chiplets and the base wafer deploys the hydrophobic containment features discussed herein.

FIG. 14 is an illustration of a cross-sectional side view of an IC structure 1400 during self-alignment bonding. As shown, IC structure 1400 includes hydrophilic structures 408 on or over a top surface 1404 of a base substrate 1401 and hydrophobic trenches 405 adjacent hydrophilic structures 408 Although illustrated with respect to hydrophilic structures 408 and hydrophobic trenches 405, any hydrophilic structures discussed herein may be deployed on or over base substrate 1401. Similarly, each of IC dies 1421 includes hydrophilic structures 818 on or over IC dies 1421 and hydrophobic trenches 601 adjacent and surrounding hydrophilic structures 818. Although illustrated with respect to hydrophilic structures 818 and hydrophobic trenches 601, any hydrophilic and hydrophobic structures discussed herein may be deployed on or over each of IC dies 1421 in any combination. Such hydrophilic and hydrophobic structures may be formed using any techniques discussed herein. In the context of IC dies 1421, such hydrophilic and hydrophobic structures may be fabricated over a host substrate and IC dies 1421 may be subsequently diced from the host substrate.

As shown, base substrate 1401 includes an active layer 1402. Active layer 1402 (or an active surface) includes a device layer and/or an interconnect layer. For example, a device layer may include transistors, capacitors, or other IC devices. An interconnect layer may be over the device layer and may include metallization levels that interconnect the devices of the device layer and provide routing to outside devices. In some embodiments, base substrate 1401 includes active devices in active layer 1402 and routing from active layer 1402 to a backside surface 1411 of base substrate 1401. In some embodiments, base substrate 1401 includes routing from active layer 1402 to backside surface 1411 and is absent active devices. Base substrate 1401 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof.

As discussed, a base substrate, base wafer, or base die indicates a substrate having active or passive electrical features. In some embodiments, a multi-level stack of IC dies is formed over base substrate 1401 using die-to-wafer bonding and 3D die complexes are segmented from base substrate 1401 such that each 3D die complex includes a portion of base substrate 1401 and the pertinent attached chiplets over the segmented portion of base substrate 1401.

Furthermore, each of IC dies 1421 includes a substrate 1423, an active layer 1422, and through vias 1424 extending between active layer 1422 and a backside surface 1407 of each of IC dies 1421. Active layer 1422 (or an active surface), similar to active layer 1402, includes a device layer and/or an interconnect layer. For example, the device layer may include transistors, capacitors, or other IC devices. The interconnect layer may be over the device layer and may include metallization levels that interconnect the devices of the device layer and provide routing to outside devices. Substrate 1423 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. Backside surface 1407 is opposite active layer 1422 and may be characterized as a non-active surface.

On or over each of IC dies 1421, hydrophilic structures 818 and hydrophobic trenches 601 (or others) are formed as discussed herein above to define hybrid bonding regions 1427. For example, hydrophilic structures 818 include metal bond pads 1414 and inorganic dielectric material 1413, which may have any characteristics discussed with respect to metal bond pads 203 and inorganic dielectric material 204. Similarly, hydrophobic trenches 601 may have any characteristics discussed herein and, although illustrated with respect to hydrophilic structures 818 and hydrophobic trenches 601 any structures discussed herein may be deployed. As discussed, the hydrophilic structures and hydrophobic structures may be formed over a wafer including one or more of IC dies 1421 using the techniques discussed above, and IC dies 1421 may be segmented (e.g., diced) from the wafer for pick and place onto hybrid bonding regions 403, for example. The combination of hydrophilic structures/hydrophobic structures over base substrate 1401 and the combination of hydrophilic structures/hydrophobic structures on IC dies 1421 may be the same or they may be different.

As shown, liquid droplets 1406 are placed on hybrid bonding regions 403 of hydrophilic structures 408 (or on hybrid bonding regions 1427 of hydrophilic structures 818). Liquid droplets 1406 may be any suitable liquid such as water of any suitable volume. Hybrid bonding regions 403 and hybrid bonding regions 1427 are brought together using, for example, pick and place of IC dies 1421. As shown, liquid droplets 1406 spread out on hybrid bonding regions 403 and are contained by hydrophobic trenches 405. IC dies 1421 are grossly and advantageously quickly aligned to hybrid bonding regions 403 by pick and place 1482. Liquid droplets 1406, confined by the self-alignment assisting features discussed herein, quickly fine align each of IC dies 1421 to the corresponding hybrid bonding region 403.

IC dies 1421 may be fabricated and attached such that they are in a face-down configuration 1431 or a face-up configuration 1432. In face-down configuration 1431, active layer 1402 and active layer 1422 are adjacent one another and are directly connected by a hybrid bond therebetween, as discussed further below. Advantageously, through vias 1424 (which may be characterized as through substrate vias or through silicon vias, TSVs), have backside connections on or over backside surface 1407 such that routing from the hybrid bond and active layer 1422 is provided to additional IC dies in the stack (e.g., extending in the z-dimension). In face-up configuration 1432, active layer 1402 is opposite substrate 1423 with respect to active layer 1422. In such contexts, through vias 1424 again have backside connections on or over backside surface 1407 such that routing from the hybrid bond may be provided to active layer 1422, and then to additional IC dies in the stack (e.g., extending in the z-dimension). Furthermore, any additional number of levels of IC dies may be coupled to IC dies 1421 to form multi-level 3D die stacks having any number of levels.

Returning to FIG. 1, process 100 continues at operation 103, where the IC dies or chiplets are bonded to the base substrate or wafer by evaporating the liquid droplets and optional anneal processing. For example, the liquid droplet applied at operation 102 evaporates relatively quickly after alignment and the inorganic materials hold the IC dies or chiplets in place due to, for example, Van der Waals forces. A subsequent anneal operation may be performed to bond the IC dies or chiplets to the bonding regions of the base wafer by melding metal bond pads and the inorganic materials therebetween.

FIG. 15 is an illustration of a cross-sectional side view of an IC structure 1500 similar to IC structure 1400 after liquid droplets 1406 evaporate and after bonding to form composite metal structures 1501 and a composite dielectric portion 1502 between each of IC dies 1421 and base substrate 1401. Furthermore, hydrophobic structures, if used, may bond to form composite hydrophobic structures (not shown). In other contexts, no bonding between hydrophobic structures, even if used, occurs. IC structure 1500 includes base substrate 1401 coupled to active layers 1422 or backside surfaces 1407 of each IC die 1421, depending on whether each IC dies was in face-down configuration 1431 or face-up configuration 1432 during bonding.

As shown, the discussed hybrid bonding forms composite metal structures 1501 and a composite dielectric portion 1502 across a bonding plane 1543. In some embodiments, bonding plane 1543 is substantially parallel to top surface 1404 as they are both in the x-y plane. Thereby, a hybrid bond 1521 between IC dies 1421 and base substrate 1401 is formed. Each hybrid bond 1521 includes composite metal structures 1501 and composite dielectric portion 1502. Composite dielectric portion 1502 may be characterized as an inorganic material, an inorganic bond layer, an inorganic bonding material, or the like. As shown, each hybrid bond 1521 is surrounded by composite hydrophobic structures 1503 which are formed by the pertinent hydrophobic structures deployed in forming hybrid bond 1521. Composite hydrophobic structures 1503 may have any characteristics discussed herein.

As shown in insert 1512, in some embodiments, adjacent metal pads are annealed to form a composite metal structure 1513 (one of composite metal structures 1501) such that metal structure 1513 has a substantially aligned sidewalls 1523. However, in other embodiments, adjacent metal pads 203, 1414 have a misalignment 1514 during anneal and form a composite metal structure 1533 such that metal structure 1533 has substantially misaligned sidewalls and therefore metal structure 1533 includes a jut 1524 and an overhang 1525. For example, the sidewall of metal structure 1533 may have substantially vertical sidewall portions and a substantially horizontal sidewall portion (e.g., at jut 1524 and overhang 1525).

As discussed, each hybrid bond 1521 is surrounded (entirely or mostly, i.e., >90%) by hydrophobic structures 1503. As shown in FIG. 15, hydrophobic structures 1503 extend around a perimeter P1 of hybrid bond 1521. As used herein, the term perimeter is used in its ordinary meaning to indicate an outer boundary of hydrophobic structure 1503 in the x-y plane. For perimeters that are not taken in the same plane, such perimeters are projected into the same plane for determination of their dimensions. Furthermore, an outer perimeter P2 of hydrophobic structure 1503 is fully within an outer perimeter P3 of IC die 1421. It is noted that a single continuous hydrophobic structure 1503 may surround hybrid bond 1521 or multiple discontinuous hydrophobic structures 1503 may surround hybrid bond 1521.

Returning to FIG. 1, process 100 continues at operation 104, where a gap fill dielectric is formed between the bonded IC dies and planarized. Such processing may be in preparation for additional levels of IC dies or, after a final level of IC dies, to provide a planar surface for attachment of a support substrate. In some embodiments, the gap fill dielectric is an inorganic dielectric material such as silicon nitride, silicon oxynitride, silicon carbonitride, or silicon carbide. However, organic dielectric materials may be used. The gap fill dielectric may be formed using any suitable technique or techniques such as deposition techniques followed by planarization.

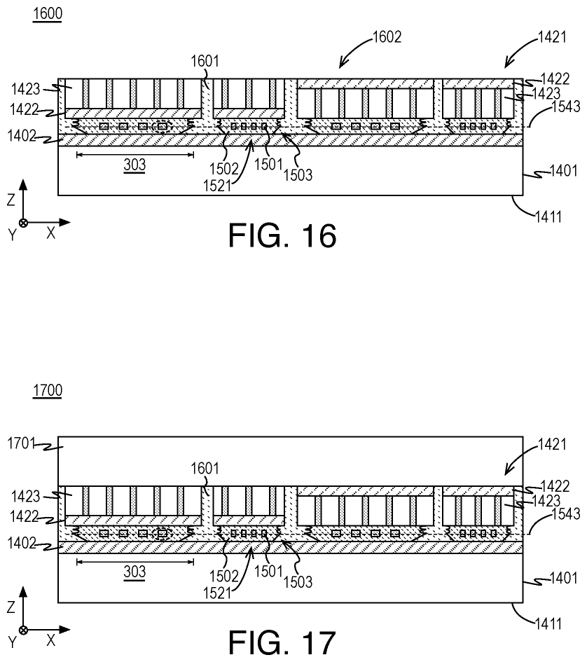

FIG. 16 is an illustration of a cross-sectional side view of IC structure 1600 similar to IC structure 1500 after forming dielectric 1601 and a substantially planar surface 1602. As shown, dielectric 1601 may be deposited as a fill material using any suitable technique or techniques such as vapor deposition techniques. The fill material is then planarized using chemical mechanical polishing techniques to form planar surface 1602. Dielectric 1601 may be any suitable dielectric material such as an inorganic dielectric material inclusive of silicon oxide, silicon nitride, silicon oxynitride, silicon carbonitride, silicon carbide, or combinations thereof (e.g., a layer of one of those materials covered by a second layer of another one of those materials). Although inorganic dielectric materials may be advantageous, organic dielectrics may be deployed. For example, gap fill by dielectric 1601 fills gaps 411, 808, 1211 and may be in any position or configuration discussed with respect to gaps 411, 808, 1211.

Returning to FIG. 1, process 100 continues at operation 105, where the multi-level die stack may be attached to a structural substrate such as a structural wafer. In some embodiments, the multi-level die stack is bonded to the structural substrate in a wafer-to-wafer bond using an adhesive, an adhesive tape, a dielectric bond, or the like. The structural substrate may be a structural wafer or panel or the like that is absent any active or passive electrical features. For example, the structural substrate may be a monolithic material, a crystalline material, or a composite material. In some embodiments, the structural substrate is monocrystalline silicon such as a silicon wafer. In some embodiments, the structural substrate is or includes germanium, silicon germanium, silicon carbide, or sapphire.

FIG. 17 is an illustration of a cross-sectional side view of IC structure 1700 similar to IC structure 1600 after bonding IC structure 1600 to a structural substrate 1701. Structural substrate 1701 may be bonded to IC structure 1600 using an adhesive, an adhesive tape, or the like (not shown). Structural substrate 1701 may be a structural wafer or panel and is absent any active or passive electrical features. In some embodiments, structural substrate 1701 is or includes monocrystalline silicon, germanium, silicon germanium, silicon carbide, or sapphire. In some embodiments, structural substrate 1701 provides structural support during further processing (e.g., dicing, packaging, assembly, etc.). For example, base substrate 1401 may be thinned while IC structure 1600 is mounted to structural substrate 1701. After such processing and during deployment in an electronic device, structural substrate 1701 may provide a heat conduction path while continuing to provide structural support.

Returning to FIG. 1, process 100 continues at operation 106, where the integrated circuit structure is segmented (or diced) from the wafer-to-wafer bonded stack. For example, IC structure 1600 may be segmented from a wafer using known dicing techniques. Process 100 continues at operation 107, where the resultant device (e.g., IC structure) may be packaged, assembled, and implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 18 illustrates an example microelectronic device assembly 1800 including a 3D die stack having a hybrid bond with dielectric material between an outer perimeter edge of a bonding structure and a substrate or an IC die, in accordance with some embodiments. As shown, IC structure 1700 may be incorporated into microelectronic device assembly 1800. Although illustrated with respect to the hydrophobic structures of FIGS. 4 and 8, IC structure 1700 and, in turn microelectronic device assembly 1800, may include any hydrophobic structures discussed herein in any combination. Microelectronic device assembly 1800 may include any number of IC structures 1700 mounted to a substrate 1811 via interconnects 1809, which are optionally embedded in a mold or underfill material 1812. Substrate 1811 may be a package substrate, interposer, or board (such as a motherboard). Any number of IC structures 1700 having the same or different hydrophobic structures may be attached to substrate 1811.

Microelectronic device assembly 1800 further includes a power supply 1856 coupled to one or more of substrate 1811 (i.e., a board, package substrate, or interposer), IC dies 1421, and/or other components of microelectronic device assembly 1800. Power supply 1856 may include a battery, voltage converter, power supply circuitry, or the like. Microelectronic device assembly 1800 further includes a thermal interface material (TIM) 1801 disposed on a top surface of structural substrate 1701. TIM 1801 may include any suitable thermal interface material and may be characterized as TIM 1. Integrated heat spreader 1802 having a surface on TIM 1801 extends over IC structure 1700 and is mounted to substrate 1811. Microelectronic device assembly 1800 further includes a TIM 1803 disposed on a top surface of integrated heat spreader 1802. TIM 1803 may include any suitable thermal interface material and may be characterized as TIM 2. TIM 1801 and TIM 1803 may be the same materials, or they may be different. A heat sink 1804 (e.g., an exemplary heat dissipation device or thermal solution) is on TIM 1803 and dissipates heat. Microelectronic device assembly 1800 may be used in desktop and server form factors. In other contexts, a heat solution such as a heat pipe or heat spreader may be mounted directly on TIM 1801. Such assemblies may be used in smaller form factor devices. Other heat dissipation devices may be used.

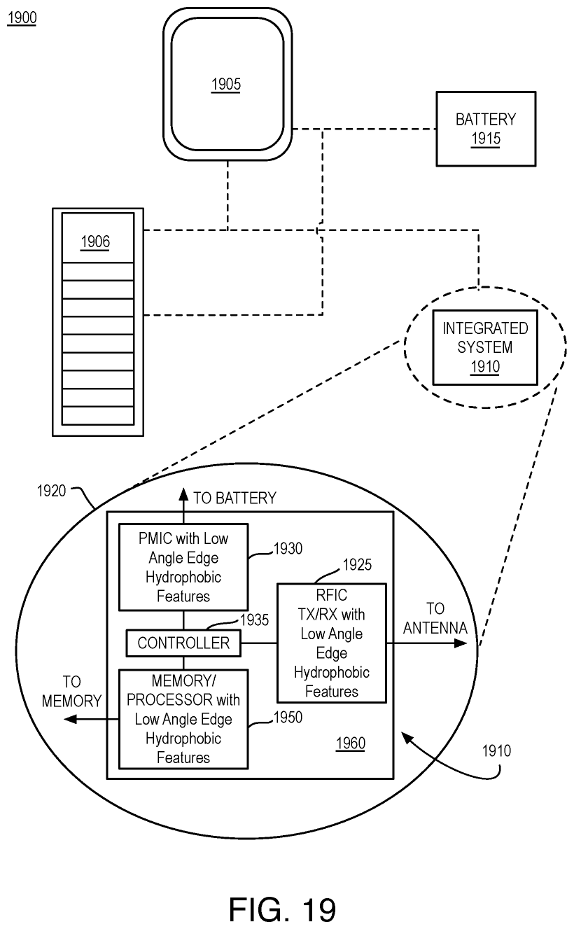

FIG. 19 illustrates exemplary systems 1900 deploying a 3D die stack having a hybrid bond with dielectric material between an outer perimeter edge of a bonding structure and a substrate or an IC die, in accordance with some embodiments. The system may be a mobile computing platform 1905 and/or a data server machine 1906, for example. Either may employ a component assembly including an IC structure as described herein. Server machine 1906 may be any commercial server, for example, including any number of high-performance computing platforms disposed within a rack and networked together for electronic data processing, which in the exemplary embodiment includes an integrated circuit (IC) die assembly with a 3D die stack having a hybrid bond with dielectric material between an outer perimeter edge of a bonding structure and a substrate or an IC die as described elsewhere herein. Mobile computing platform 1905 may be any portable device configured for each of electronic data display, electronic data processing, wireless electronic data transmission, or the like. For example, mobile computing platform 1905 may be any of a tablet, a smart phone, a laptop computer, etc., and may include a display screen (e.g., a capacitive, inductive, resistive, or optical touchscreen), a chip-level or package-level integrated system 1910, and a battery 1915. Although illustrated with respect to mobile computing platform 1905, in other examples, chip-level or package-level integrated system 1910 and a battery 1915 may be implemented in a desktop computing platform, an automotive computing platform, an internet of things platform, or the like. As discussed below, in some examples, the disclosed systems may include a sub-system 1960 such as a system on a chip (SOC) or an integrated system of multiple ICs, which is illustrated with respect to mobile computing platform 1905.

Whether disposed within integrated system 1910 illustrated in expanded view 1920 or as a stand-alone packaged device within data server machine 1906, sub-system 1960 may include memory circuitry and/or processor circuitry 1950 (e.g., RAM, a microprocessor, a multi-core microprocessor, graphics processor, etc.), a power management integrated circuit (PMIC) 1930, a controller 1935, and a radio frequency integrated circuit (RFIC) 1925 (e.g., including a wideband RF transmitter and/or receiver (TX/RX)). As shown, one or more IC dice, such as memory circuitry and/or processor circuitry 1950 may be packaged, assembled and implemented, such that the package has a 3D die stack having a hybrid bond with dielectric material between an outer perimeter edge of a bonding structure and a substrate or an IC die as described herein. In some embodiments, RFIC 1925 includes a digital baseband and an analog front-end module further comprising a power amplifier on a transmit path and a low noise amplifier on a receive path). Functionally, PMIC 1930 may perform battery power regulation, DC-to-DC conversion, etc., and so has an input coupled to battery 1915, and an output providing a current supply to other functional modules. As further illustrated in FIG. 19, in the exemplary embodiment, RFIC 1925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1950 may provide memory functionality, high level control, data processing and the like for sub-system 1960. In alternative implementations, each of the SOC modules may be integrated onto separate ICs coupled to a package substrate, interposer, or board.

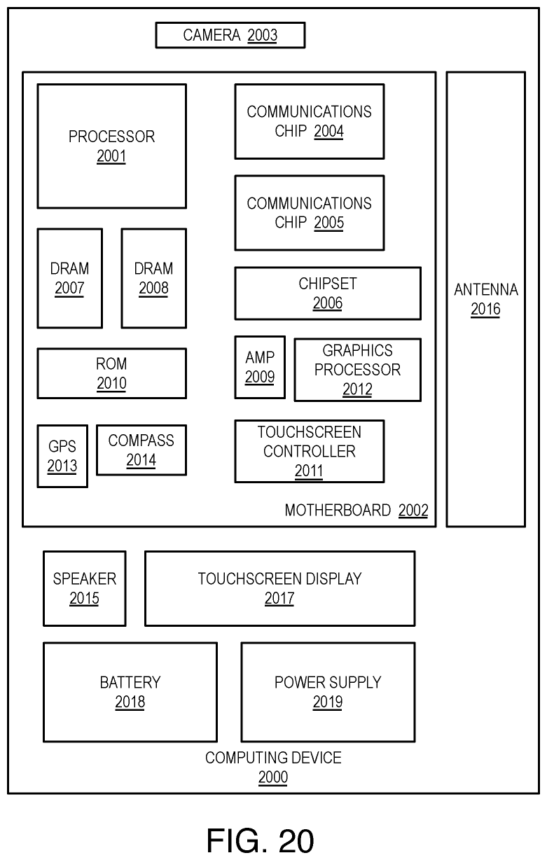

FIG. 20 is a functional block diagram of an electronic computing device 2000, in accordance with some embodiments. For example, device 2000 may, via any suitable component therein, employ a 3D die stack having a hybrid bond with dielectric material between an outer perimeter edge of a bonding structure and a substrate or an IC die in accordance with any embodiments described elsewhere herein. Device 2000 further includes a motherboard or package substrate 2002 hosting a number of components, such as, but not limited to, a processor 2001 (e.g., an applications processor). Processor 2001 may be physically and/or electrically coupled to package substrate 2002. In some examples, processor 2001 is within a packaged IC assembly that includes a 3D die stack having a hybrid bond with dielectric material between an outer perimeter edge of a bonding structure and a substrate or an IC die as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 2004, 2005 may also be physically and/or electrically coupled to the package substrate 2002. In further implementations, communication chips 2004, 2005 may be part of processor 2001. Depending on its applications, computing device 2000 may include other components that may or may not be physically and electrically coupled to package substrate 2002. These other components include, but are not limited to, volatile memory (e.g., DRAM 2007, 2008), non-volatile memory (e.g., ROM 2010), flash memory (e.g., NAND or NOR), magnetic memory, a graphics processor 2012, a digital signal processor, a crypto processor, a chipset 2006, an antenna 2016, touchscreen display 2017, touchscreen controller 2011, battery 2018, a power supply 2019, audio codec, video codec, power amplifier 2009, global positioning system (GPS) device 2013, compass 2014, accelerometer, gyroscope, speaker 2015, camera 2003, and mass storage device (such as hard disk drive, solid-state drive (SSD), compact disk (CD), digital versatile disk (DVD), and so forth, or the like.

Communication chips 2004, 2005 may enable wireless communications for the transfer of data to and from the computing device 2000. The term “wireless” and its derivatives may be used to describe circuits, devices, systems, methods, techniques, communications channels, etc., that may communicate data through the use of modulated electromagnetic radiation through a non- solid medium. The term does not imply that the associated devices do not contain any wires, although in some embodiments they might not. Communication chips 2004, 2005 may implement any of a number of wireless standards or protocols, including, but not limited to, those described elsewhere herein. As discussed, computing device 2000 may include a plurality of communication chips 2004, 2005. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a substrate comprising an interconnect layer, and an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material, such that the hybrid bond comprises an outer edge and a center region, and the inorganic dielectric material has a sidewall portion extending inwardly from adjacent the bonding plane toward the center region.

In one or more second embodiments, further to the first embodiments, the sidewall portion of inorganic dielectric material and the bonding plane forms an angle that is not more than 60 degrees.

In one or more third embodiments, further to the first or second embodiments, the angle is not more than 15 degrees.

In one or more fourth embodiments, further to the first through third embodiments, the sidewall portion comprises a substantially planar surface that extends inwardly from adjacent the bonding plane to the top surface of the substrate or a surface of the IC die.

In one or more fifth embodiments, further to the first through fourth embodiments, the sidewall portion comprises a region of one of a plurality of scallops extending from the outer edge of the hybrid bond.

In one or more sixth embodiments, further to the first through fifth embodiments, the sidewall portion is adjacent a second sidewall portion extending substantially vertically above the sidewall portion, the second sidewall portion having a vertical thickness of not more than 100 nm.

In one or more seventh embodiments, further to the first through sixth embodiments, the apparatus further comprises a hydrophobic material layer on the sidewall portion of the inorganic dielectric material.

In one or more eighth embodiments, further to the first through seventh embodiments, the sidewall portion of the inorganic dielectric material is in direct contact with a second dielectric material.

In one or more ninth embodiments, further to the first through eighth embodiments, the substrate and the IC die are part of an IC structure further comprising a structural substrate, the apparatus further comprising a power supply coupled to the IC structure.

In one or more tenth embodiments, an apparatus comprises a substrate comprising an interconnect layer, an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material, and a metal structure extending from an edge of the inorganic dielectric material and substantially surrounding the hybrid bond, the metal structure having a thickness less than a thickness of one or more of the interconnect structures.

In one or more eleventh embodiments, further to the tenth embodiments, a second dielectric material is between the metal structure and the top surface of the substrate or a surface of the IC die.

In one or more twelfth embodiments, further to the tenth or eleventh embodiments, the thickness of one or more of the interconnect structures is not less than 500 nm and the thickness of the metal structure is not more than 50 nm.

In one or more thirteenth embodiments, further to the tenth through twelfth embodiments, the metal structure and the metal interconnect structures both comprise copper.

In one or more fourteenth embodiments, further to the tenth through thirteenth embodiments, the apparatus further comprises a hydrophobic material layer on a portion of the metal structure.

In one or more fifteenth embodiments, further to the tenth through fourteenth embodiments, the substrate, the IC die, and the metal structure are part of an IC structure further comprising a structural substrate, the apparatus further comprising a power supply coupled to the IC structure.

In one or more sixteenth embodiments, a method comprises patterning a trench around a first hybrid bonding structure and over a substrate, the first hybrid bonding structure comprising exposed first metal pads interspersed in a first inorganic dielectric material, wherein said patterning of the trench removes at least a portion of the first inorganic dielectric material from under an upper perimeter edge of the first hybrid bonding structure to form a gap between the upper perimeter edge and a surface of the substrate, evaporating a liquid droplet from between the first hybrid bonding structure and a second hybrid bonding structure over a second substrate to bond the first and second hybrid bonding structures, and bonding the first metal pads and first inorganic dielectric material to second metal pads and a second inorganic dielectric material of the second hybrid bonding structure.

In one or more seventeenth embodiments, further to the sixteenth embodiments, removing the portion of the first inorganic dielectric material comprises forming a sidewall surface having a substantially constant inward taper from the upper perimeter edge to the surface of the substrate.

In one or more eighteenth embodiments, further to the sixteenth or seventeenth embodiments, removing the portion of the first inorganic dielectric material comprises forming a plurality of scallops in the first inorganic dielectric material between the upper perimeter edge and the surface of the substrate.

In one or more nineteenth embodiments, further to the sixteenth through eighteenth embodiments, the upper perimeter edge of the first hybrid structure comprises a metal structure having a thickness less than a thickness of one or more of the first metal pads.

In one or more twentieth embodiments, further to the sixteenth through nineteenth embodiments, forming the metal structure comprises a metal deposition operation that forms a top portion of each of the first metal pads.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a substrate comprising an interconnect layer; and
an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material,
wherein the hybrid bond comprises an outer edge and a center region, and the inorganic dielectric material has a sidewall portion extending inwardly from adjacent the bonding plane toward the center region.

2. The apparatus of claim 1, wherein the sidewall portion of inorganic dielectric material and the bonding plane forms an angle that is not more than 60 degrees.

3. The apparatus of claim 2, wherein the angle is not more than 15 degrees.

4. The apparatus of claim 1, wherein the sidewall portion comprises a substantially planar surface that extends inwardly from adjacent the bonding plane to the top surface of the substrate or a surface of the IC die.

5. The apparatus of claim 1, wherein the sidewall portion comprises a region of one of a plurality of scallops extending from the outer edge of the hybrid bond.

6. The apparatus of claim 5, wherein the sidewall portion is adjacent a second sidewall portion extending substantially vertically above the sidewall portion, the second sidewall portion having a vertical thickness of not more than 100 nm.

7. The apparatus of claim 1, further comprising a hydrophobic material layer on the sidewall portion of the inorganic dielectric material.

8. The apparatus of claim 1, wherein the sidewall portion of the inorganic dielectric material is in direct contact with a second dielectric material.

9. The apparatus of claim 1, wherein the substrate and the IC die are part of an IC structure further comprising a structural substrate, the apparatus further comprising a power supply coupled to the IC structure.

10. An apparatus, comprising:
a substrate comprising an interconnect layer;
an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material; and
a metal structure extending from an edge of the inorganic dielectric material and substantially surrounding the hybrid bond, the metal structure having a thickness less than a thickness of one or more of the interconnect structures.

11. The apparatus of claim 10, wherein a second dielectric material is between the metal structure and the top surface of the substrate or a surface of the IC die.

12. The apparatus of claim 10, wherein the thickness of one or more of the interconnect structures is not less than 500 nm and the thickness of the metal structure is not more than 50 nm.

13. The apparatus of claim 10, wherein the metal structure and the metal interconnect structures both comprise copper.

14. The apparatus of claim 10, further comprising a hydrophobic material layer on a portion of the metal structure.

15. The apparatus of claim 10, wherein the substrate, the IC die, and the metal structure are part of an IC structure further comprising a structural substrate, the apparatus further comprising a power supply coupled to the IC structure.

16. A method, comprising:
patterning a trench around a first hybrid bonding structure and over a substrate, the first hybrid bonding structure comprising exposed first metal pads interspersed in a first inorganic dielectric material, wherein said patterning of the trench removes at least a portion of the first inorganic dielectric material from under an upper perimeter edge of the first hybrid bonding structure to form a gap between the upper perimeter edge and a surface of the substrate;
evaporating a liquid droplet from between the first hybrid bonding structure and a second hybrid bonding structure over a second substrate to bond the first and second hybrid bonding structures; and
bonding the first metal pads and first inorganic dielectric material to second metal pads and a second inorganic dielectric material of the second hybrid bonding structure.

17. The method of claim 16, wherein removing the portion of the first inorganic dielectric material comprises forming a sidewall surface having a substantially constant inward taper from the upper perimeter edge to the surface of the substrate.

18. The method of claim 16, wherein removing the portion of the first inorganic dielectric material comprises forming a plurality of scallops in the first inorganic dielectric material between the upper perimeter edge and the surface of the substrate.

19. The method of claim 16, wherein the upper perimeter edge of the first hybrid structure comprises a metal structure having a thickness less than a thickness of one or more of the first metal pads.

20. The method of claim 19, wherein forming the metal structure comprises a metal deposition operation that forms a top portion of each of the first metal pads.
